(19) United States
(12) Patent Application Publication
(10) Pub. No.: US 2023/0290854 A1
(43) Pub. Date: Sep. 14, 2023

(54) SEMICONDUCTOR DEVICE AND METHOD FOR MANUFACTURING SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kouta TOMITA, Nonoichi Ishikawa (JP); Tatsuya SHIRAISHI, Nonoichi Ishikawa (JP); Tatsuya NISHIWAKI, Yokohama Kanagawa (JP)

(21) Appl. No.: 17/901,304

(22) Filed: Sep. 1, 2022

(30) Foreign Application Priority Data
Mar. 9, 2022 (JP) 2022-036422

(51) Int. Cl. H01L 29/49; H01L 29/06; H01L 29/40; H01L 29/417; H01L 29/66

(52) U.S. Cl. CPC H01L 29/4916; H01L 29/0653; H01L 29/401; H01L 29/41775; H01L 29/66568

(57) ABSTRACT

A semiconductor device includes a semiconductor layer, a first insulating film provided on the semiconductor layer, a gate wiring provided on the first insulating film, and a source electrode provided on the first insulating film. The device further includes a second insulating film provided on the gate wiring and the source electrode and including a portion sandwiched between the gate wiring and the source electrode, and a drain electrode provided below the semiconductor layer. Further, an upper surface of the first insulating film includes a first region having a first concentration of phosphorus and a second region having a second concentration of phosphorus that is higher than the first concentration. The first region is present between the semiconductor layer and the gate wiring or the source electrode, and the second region is present between the semiconductor layer and the portion of the second insulating film.

### CROSS-REFERENCE TO RELATED APPLICATION(S)

This application is based upon and claims the benefit of priority from Japanese Patent Application No. 2022-036422, filed Mar. 9, 2022, the entire contents of which are incorporated herein by reference.

### FIELD

Embodiments described herein relate generally to a semiconductor device and a method for manufacturing the same.

### BACKGROUND

A power transistor is provided with a source electrode and a gate wiring electrically connected to a gate electrode. At least a part of the source electrode and the gate wiring is formed on an insulating film. When the insulating film contains phosphorus (P), phosphorus may adversely influence performance of the power transistor.

### DESCRIPTION OF THE DRAWINGS

FIG. 1 is a cross-sectional view showing a structure of a semiconductor device according to a first embodiment.

FIG. 2 is a plan view showing the structure of the semiconductor device according to the first embodiment.

FIG. 3 is another cross-sectional view showing the structure of the semiconductor device according to the first embodiment.

FIG. 4 is still another cross-sectional view showing the structure of the semiconductor device according to the first embodiment.

FIG. 5 is yet still another cross-sectional view showing the structure of the semiconductor device according to the first embodiment.

FIG. 6 is another plan view showing the structure of the semiconductor device according to the first embodiment.

FIG. 7 is a cross-sectional view showing a structure of a semiconductor device according to a modification of the first embodiment.

FIG. 8 is a plan view showing the structure of the semiconductor device according to the modification of the first embodiment.

FIG. 9 is a cross-sectional view showing a structure of a semiconductor device according to a first comparative example.

FIG. 10 is a cross-sectional view showing a structure of a semiconductor device according to a second comparative example.

FIGS. 11A to 11C are cross-sectional views showing a first example of a method for manufacturing the semiconductor device according to the first embodiment.

FIGS. 12A to 12C are cross-sectional views showing a second example of the method for manufacturing the semiconductor device according to the first embodiment.

FIGS. 13A to 13C are cross-sectional views showing a third example of the method for manufacturing the semiconductor device according to the first embodiment.

FIGS. 14A, 14B, 15A, 15B, 16A, 16B, 17A, 17B, 18A, 18B, 19A, 19B, 20A, 20B, 21A, 21B, 22A, and 22B are cross-sectional views showing details of the method for manufacturing the semiconductor device according to the first embodiment.

### DETAILED DESCRIPTION

Embodiments provide a semiconductor device and a method for manufacturing the same.

In general, according to one embodiment, a semiconductor device includes a semiconductor layer, a first insulating film provided on the semiconductor layer, a gate wiring provided on the first insulating film, and a source electrode provided on the first insulating film. The device further includes a second insulating film provided on the gate wiring and the source electrode and including a portion sandwiched between the gate wiring and the source electrode, and a drain electrode provided below the semiconductor layer. Further, an upper surface of the first insulating film includes a first region having a first concentration of phosphorus and a second region having a second concentration of phosphorus that is higher than the first concentration. The first region is present between the semiconductor layer and the gate wiring or the source electrode, and the second region is present between the semiconductor layer and the portion of the second insulating film.

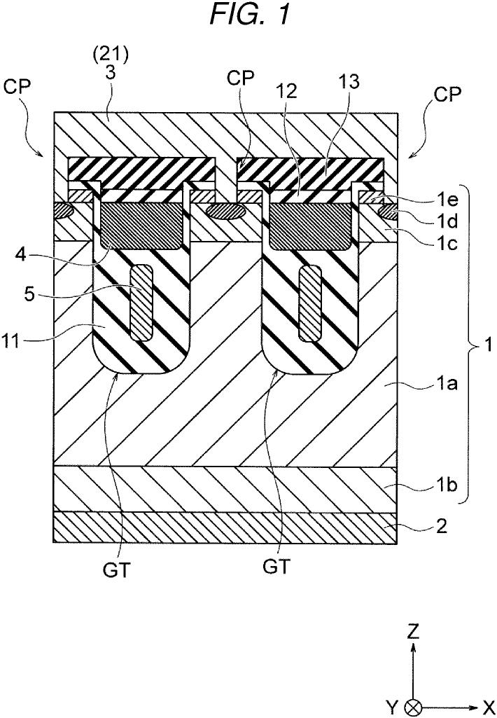

Hereinafter, embodiments of the present disclosure will be described with reference to the drawings. In FIG. 1 to FIGS. 22A and 22B, the same components are denoted by the same reference signs, and redundant description will be omitted.

### First Embodiment

### (1) Structure of Semiconductor Device

FIG. 1 is a cross-sectional view showing a structure of a semiconductor device according to a first embodiment. FIG. 1 shows a cross section of a transistor in the semiconductor device according to the present embodiment. The transistor is, for example, a power MOSFET having a trench gate structure.

The semiconductor device according to the present embodiment includes a semiconductor layer 1, a drain electrode 2, a source electrode 3, a plurality of gate trenches GT, and a plurality of contact portions CP. The semiconductor device according to the present embodiment further includes a gate electrode 4, a field plate electrode 5, an insulating film 11, and an insulating film 12 in each of the gate trenches GT. The semiconductor device according to the present embodiment further includes an insulating film 13.

The semiconductor layer 1 includes a drift layer 1a and a drain layer 1b. The semiconductor layer 1 further includes a base layer 1c, a contact layer 1d, and a source layer 1e for each of the contact portions CP shown in FIG. 1.

Hereinafter, the structure of the semiconductor device according to the present embodiment will be described with reference to FIG. 1.

The semiconductor layer 1 includes, for example, a plurality of impurity semiconductor layers to be described later. The semiconductor layer 1 includes a semiconductor substrate, such as a silicon (Si) substrate. FIG. 1 shows an X direction and a Y direction parallel to an upper surface and a lower surface of the semiconductor layer 1 and perpendicular to each other, and a Z direction perpendicular to the upper surface and the lower surface of the semiconductor layer 1. In the present description, a +Z direction is treated as an upward direction, and a -Z direction is treated as a downward direction. The -Z direction may or may not coincide with a gravitational direction. The upper surface and the lower surface of the semiconductor layer 1 are an example of a first surface and a second surface, respectively.

The drift layer 1a is an n-type layer provided in the semiconductor layer 1. The drain layer 1b is an n-type layer provided in the semiconductor layer 1, and is disposed below the drift layer 1a. The base layer 1c is a p-type layer provided in the semiconductor layer 1, and is disposed on the drift layer 1a between the gate trenches GT. The contact layer 1d is a p⁺-type layer provided in the semiconductor layer 1, and is disposed on the corresponding base layer 1c between the gate trenches GT. The source layer 1e is an n-type layer provided in the semiconductor layer 1, and is disposed on the corresponding base layer 1c between the gate trenches GT. The plurality of gate trenches GT are formed in the semiconductor layer 1 on an upper surface side of the semiconductor layer 1, each extending in the Y direction, and are adjacent to each other in the X direction.

The p⁺-type layer and an n⁺-type layer are layers respectively containing a p-type impurity and an n-type impurity having a concentration higher than a concentration of the p-type impurity and the n-type impurity in the p-type layer and the n-type layer. In addition, a p-type layer and the n-type layer are layers respectively containing the p-type impurity and the n-type impurity having a concentration higher than the concentration of the p-type impurity and the n-type impurity in the p⁻-type layer and the n⁻-type layer.

The drain electrode 2 is formed on the lower surface of the semiconductor layer 1. The drain electrode 2 is in contact with the drain layer 1b. The drain electrode 2 is, for example, a metal layer such as an aluminum (Al) layer or a gold (Au) layer.

The source electrode 3 is formed on the upper surface of the semiconductor layer 1. The source electrode 3 includes a plurality of contact portions CP, each of which is in contact with the corresponding contact layer 1d and source layer 1e. The source electrode 3 is formed of, for example, a metal such as aluminum (Al).

The gate electrode 4 and the field plate electrode 5 are formed in the corresponding gate trench GT on or in the insulating film 11. In FIG. 1, the gate electrode 4 is formed on the insulating film 11 and below the insulating film 12, and the field plate electrode 5 is formed in the insulating film 11. The gate electrode 4 is, for example, a polysilicon layer or a metal layer. The field plate electrode 5 is, for example, a polysilicon layer or a metal layer. The insulating film 11 is, for example, a silicon oxide film (SiO₂ film). The insulating film 12 is, for example, a SiO₂ film. In the gate trench GT, the gate electrode 4 and the field plate electrode 5 each extend in the Y direction, and the gate electrode 4 is disposed above the field plate electrode 5.

The insulating film 13 is formed on the upper surface of the semiconductor layer 1 and is sandwiched between the semiconductor layer 1 and the source electrode 3. The contact portion CP of the source electrode 3 is formed through the insulating film 13. The insulating film 13 is further formed on the insulating films 11 and 12 in the gate trench GT. The insulating film 11 electrically insulates the gate electrode 4 from the field plate electrode 5, and the insulating films 12 and 13 electrically insulate the gate electrode 4 from the source electrode 3. The insulating film 13 is, for example, a SiO₂ film. The insulating film 13 may be a film other than the SiO₂ film (for example, a silicon oxynitride film (a SiON film)). Further details of the insulating film 13 will be described later.

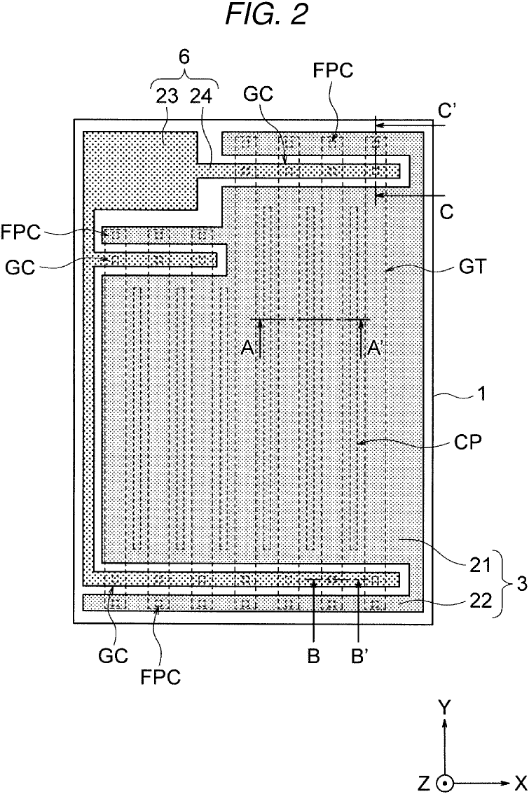

FIG. 2 is a plan view showing the structure of the semiconductor device according to the first embodiment. FIG. 1 shows a cross section taken along a line A-A′ in FIG. 2.

FIG. 2 shows the source electrode 3 and a gate wiring 6 formed on the semiconductor layer 1. The source electrode 3 includes a planar portion 21 having a planar shape and a plurality of linear portions 22 each having a linear shape extending from the planar portion 21. The source electrode 3 shown in FIG. 1 is the planar portion 21 of the source electrode 3.

The gate wiring 6 includes a pad portion 23 having a planar shape and a plurality of wiring portions 24 each having a linear shape extending from the pad portion 23. The pad portion 23 of the gate wiring 6 is used as, for example, a bonding pad for electrically connecting bonding wires. In FIG. 2, in the Y direction, each wiring portion 24 of the gate wiring 6 is sandwiched between the planar portion 21 and one linear portion 22 of the source electrode 3.

Similar to FIG. 1, FIG. 2 further shows the plurality of gate trenches GT formed in the semiconductor layer 1. These gate trenches GT each extend in the Y direction, and are adjacent to each other in the X direction. Similar to FIG. 1, FIG. 2 further shows the plurality of contact portions CP that are a part of the source electrode 3 (in particular, the planar portion 21). These contact portions CP each extend in the Y direction, and are adjacent to each other in the X direction. Each of the contact portion CP is disposed between two gate trenches GT.

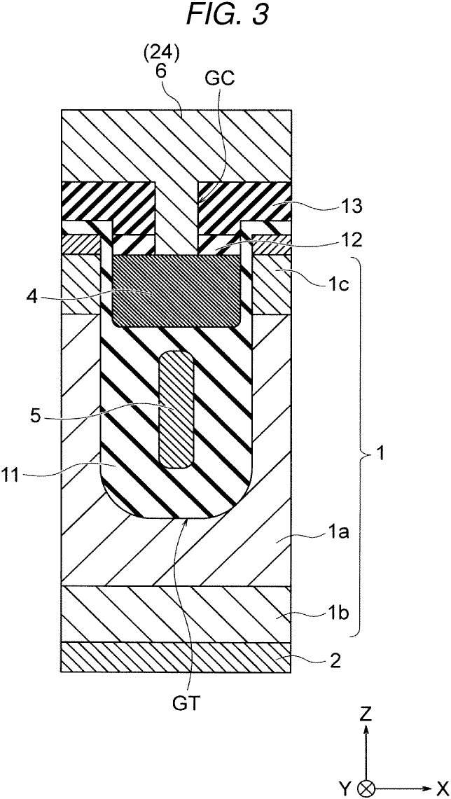

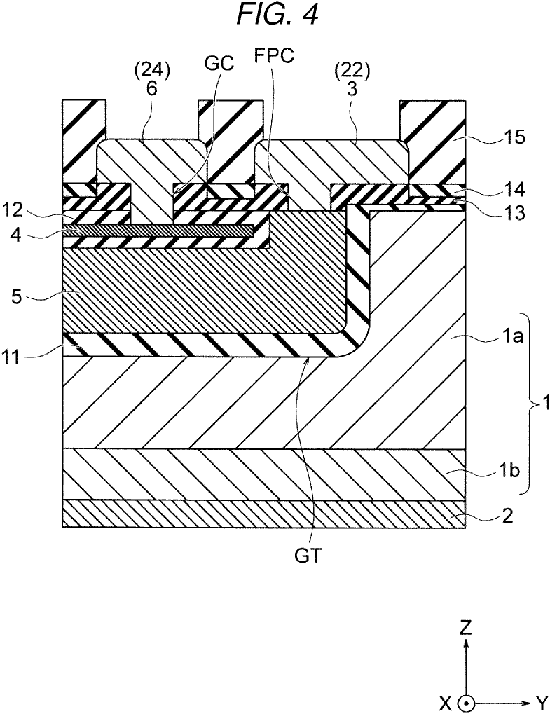

FIG. 2 further shows a plurality of field plate contacts FPC that are a part of the source electrode 3 (in particular, the linear portions 22) and gate contacts GC that are a part of the gate wiring 6 (in particular, the wiring portions 24). One field plate contact FPC is disposed on one gate trench GT, and electrically connects one field plate electrode 5 (FIG. 1) in the gate trench GT to the source electrode 3. One gate contact GC is disposed on one gate trench GT, and electrically connects one gate electrode 4 (FIG. 1) in the gate trench GT to the gate wiring 6. Further details of the field plate contacts FPC and the gate contacts GC will be described later with reference to FIGS. 3 and 4.

FIG. 3 is another cross-sectional view showing the structure of the semiconductor device according to the first embodiment. FIG. 3 shows a cross section taken along a line B-B′ in FIG. 2. FIG. 1 shows a cross section of the source electrode 3 (in particular, the planar portion 21), whereas FIG. 3 shows a cross section of the gate wiring 6 (in particular, the wiring portion 24).

The gate wiring 6 is formed on the upper surface of the semiconductor layer 1. The gate wiring 6 includes a plurality of gate contacts GC, and FIG. 3 shows one of these gate contacts GC. The gate contact GC is in contact with the gate electrode 4 in the corresponding gate trench GT. The gate wiring 6 is formed of, for example, a metal such as aluminum (Al). The insulating film 13 is sandwiched between the semiconductor layer 1 and the gate wiring 6, and the gate contact GC of the gate wiring 6 is formed through the insulating film 13.

FIG. 4 is still another cross-sectional view showing the structure of the semiconductor device according to the first embodiment. FIG. 4 shows a cross section taken along a line C-C′ in FIG. 2. FIG. 4 shows cross sections of the source electrode 3 (in particular, the linear portion 22) and the gate wiring 6 (in particular, the wiring portion 24).

The source electrode 3 includes a plurality of field plate contacts FPC, and FIG. 4 shows one of these field plate contacts FPC. The field plate contacts FPC is in contact with the field plate electrode 5 in the corresponding gate trench GT. The insulating film 13 is sandwiched between the semiconductor layer 1 and the source electrode 3, and the field plate contact FPC of the source electrode 3 is formed through the insulating film 13.

The semiconductor device according to the present embodiment further includes an insulating film 14 and an insulating film 15. The insulating film 14 is formed on the insulating film 13. The insulating film 14 is, for example, a SiO₂ film. The insulating film 14 may be a film other than the SiO₂ film (for example, a SiON film). Further details of the insulating film 14 will be described later. The insulating film 15 is formed on the source electrode 3, the gate wiring 6, and the insulating film 14 such that an upper surface of the source electrode 3 and an upper surface of the gate wiring 6 are partially exposed. The insulating film 15 is, for example, a stacked film including a SiO₂ film, a silicon nitride film (a SiN film), and a polyimide in this order. The insulating film 15 corresponds to a passivation insulating film.

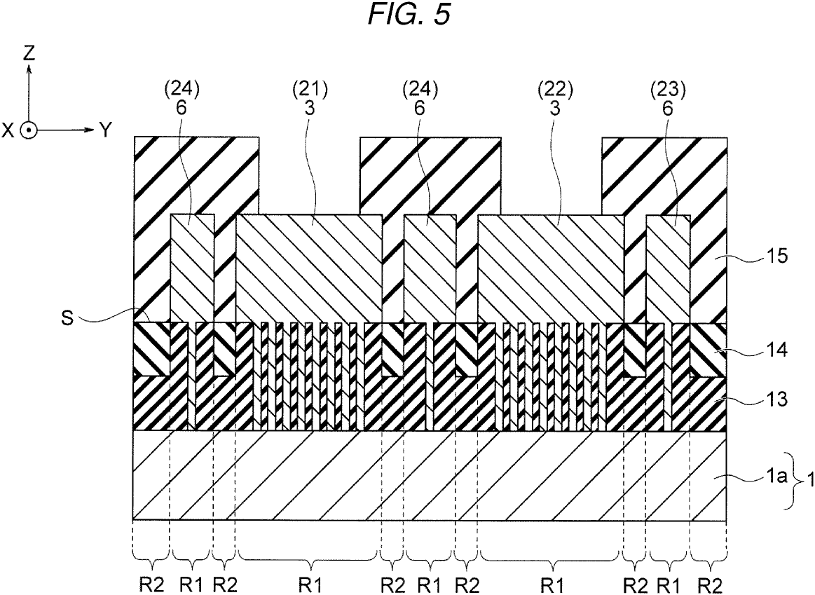

Next, the structure of the semiconductor device according to the present embodiment will be described in detail with reference to FIGS. 5 to 8.

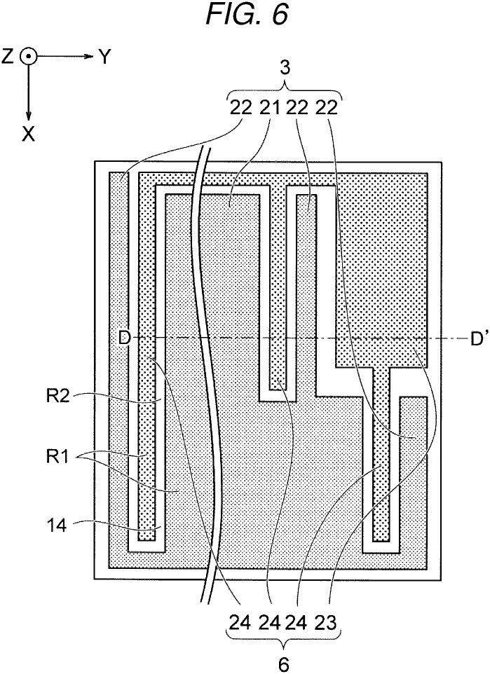

FIG. 5 is yet still another cross-sectional view showing the structure of the semiconductor device according to the first embodiment. FIG. 6 is another plan view showing the structure of the semiconductor device according to the first embodiment.

Similar to FIG. 2, FIG. 6 shows the source electrode 3 and the gate wiring 6 formed on the semiconductor layer 1. It is noted that FIG. 6 shows a plan view obtained by rotating the plan view shown in FIG. 2 by 90° in a clockwise direction. The source electrode 3 includes one planar portion 21 having a planar shape and three linear portions 22 each having a linear shape extending from the planar portion 21. The gate wiring 6 includes one pad portion 23 having a planar shape and three wiring portions 24 each having a linear shape extending from the pad portion 23.

FIG. 5 shows a cross section taken along a line D-D′ in FIG. 6. Therefore, FIG. 5 shows one planar portion 21 and one linear portion 22 (of the source electrode 3), and one pad portion 23 and two wiring portions 24 (of the gate wiring 6). It is noted that, in order to make the drawing easy to see, the cross section shown in FIG. 5 is shown with a width of the planar portion 21 in the X direction and a width of the pad portion 23 in the X direction being shorter than widths thereof in FIG. 6. In the following description, details of the insulating films 13 and 14 according to the present embodiment will be described. Therefore, in FIG. 5, other elements (the drain electrode 2, the gate electrodes 4, the field plate electrodes 5, the insulating film 11, the insulating film 12, the gate trenches GT, and the like) of the semiconductor device according to the present embodiment are omitted. Structures of these omitted elements are the same as structures described with reference to FIGS. 1 to 4.

Hereinafter, the details of the insulating films 13 and 14 according to the present embodiment will be described with reference to FIG. 5. In the description, FIG. 6 is also referred to, as appropriate. The following description is applicable not only to the structures shown in FIGS. 5 and 6 but also to the structures shown in FIGS. 1 to 4.

FIG. 5 shows an upper surface S of a base insulating film including the insulating film 13 and the insulating film 14. The base insulating film is formed on the semiconductor layer 1 as a base of the source electrode 3 and the gate wiring 6. As described above, the insulating film 14 according to the present embodiment is formed on the insulating film 13 and to be within the insulating film 13 (see FIG. 4). Therefore, the upper surface S of the base insulating film includes an upper surface of the insulating film 13 and an upper surface of the insulating film 14.

The insulating films 13 and 14 are, for example, SiO₂ films. In more detail, the insulating film 13 is, for example, a non-doped silicate glass (NSG) film. The insulating film 13 contains silicon (Si) and oxygen (O), and does not contain intentionally doped elements. Meanwhile, the insulating film 14 is, for example, a phospho-silicate glass (PSG) film. The insulating film 14 contains silicon (Si), oxygen (O), and phosphorus (P).

Therefore, a P concentration in the insulating film 14 is higher than a P concentration in the insulating film 13. In the present embodiment, the insulating film 14 contains P atoms in a high concentration, and the insulating film 13 does not contain P atoms or contains the P atoms in a low concentration. For example, when the P atoms in the insulating film 14 diffuse into the insulating film 13 for some reason, the insulating film 13 also contains the P atoms. A value of the P concentration in the insulating film 13 is, for example, less than 1.0 × 10¹⁸ cm⁻³. A value of the P concentration in the insulating film 14 is, for example, 1.0 × 10¹⁸ cm⁻³ to 1.0 × 10²² cm⁻³. When the insulating film 13 does not contain the P atoms, the value of the P concentration in the insulating film 13 is 0.

The upper surface S of the base insulating film according to the present embodiment includes regions R1 where the upper surface of the insulating film 13 does not contact the insulating film 14 and regions R2 where the insulating film 14 is above the insulating film 13. In the present embodiment, the region R2 contains the P atoms in a high concentration, and the region R1 does not contain P atoms or contains the P atoms in a low concentration. As described above, the P concentration in the region R1 is, for example, less than 1.0 × 10¹⁸ cm⁻³. Meanwhile, the P concentration in the region R2 is, for example, 1.0 × 10¹⁸ cm⁻³ to 1.0 × 10²² cm⁻³. The region R1 is an example of a first region, and the region R2 is an example of a second region.

In the present embodiment, the region R1 is present below the source electrode 3 and the gate wiring 6, and the region R2 is present between the source electrode 3 and the gate wiring 6. Therefore, the region R1 is in contact with a lower surface of the source electrode 3 and a lower surface of the gate wiring 6. Meanwhile, the region R2 is sandwiched between the source electrode 3 and the gate wiring 6 in a plan view, and is in contact with a lower surface of the insulating film 15. The same arrangement of the insulating films 14 and 15 is shown in FIG. 4 described above.

In FIG. 5, the region R1 is present between the semiconductor layer 1 and the source electrode 3 or the gate wiring 6. In addition, the insulating film 15 includes a portion sandwiched between the source electrode 3 and the gate wiring 6, and the region R2 is present between the semiconductor layer 1 and such portion of the insulating film 15.

Here, a relation between the regions R1 and R2 and a portion of the source electrode 3 or the gate wiring 6 above the upper surface S will be described. In the present embodiment, the region R1 is present below the source electrode 3 or the gate wiring 6, but is not present between the source electrode 3 and the gate wiring 6. Similarly, the region R2 is present between the source electrode 3 and the gate wiring 6 but is not present below the source electrode 3 or the gate wiring 6.

In FIG. 6, a region occupied by the source electrode 3 and the gate wiring 6 is indicated by dot hatching, and other regions are indicated by white. The region R1 according to the present embodiment coincides with the region indicated by dot hatching. Meanwhile, the region R2 according to the present embodiment coincides with the region indicated by white.

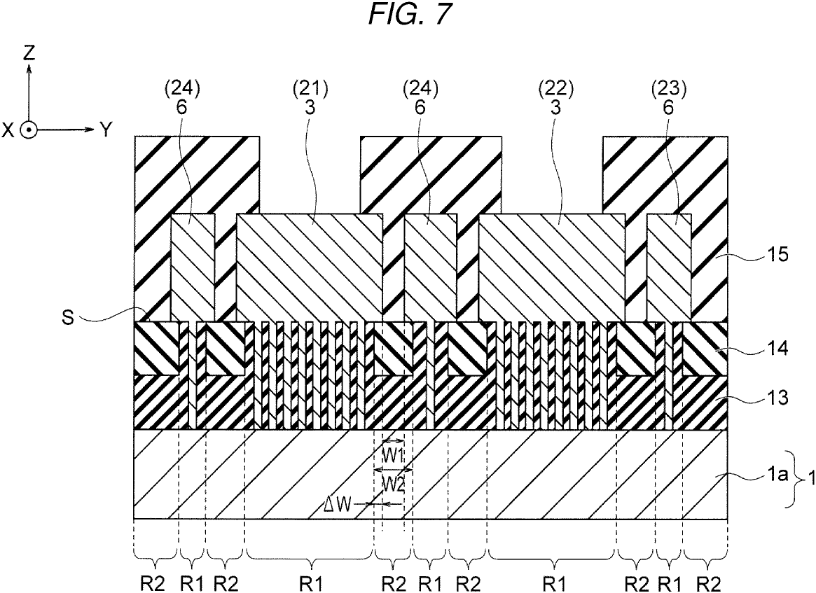

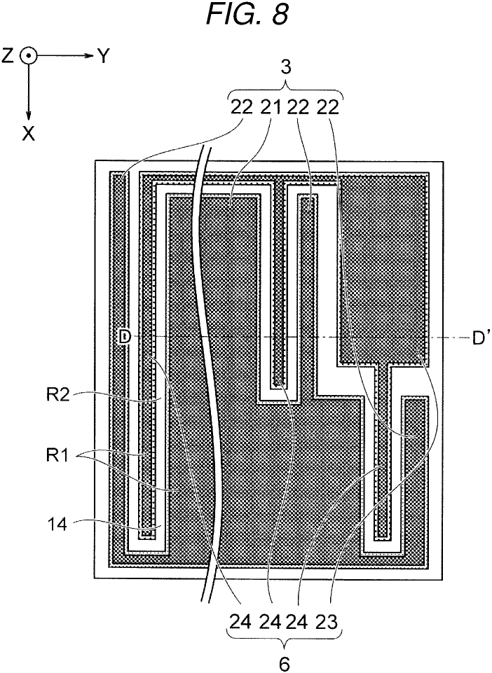

In some cases, the region R1 may expand to the region between the source electrode 3 and the gate wiring 6, and the region R2 may expand to the region below the source electrode 3 and the gate wiring 6. An example of such regions R1 and R2 will be described with reference to FIGS. 7 and 8.

As the insulating film 14, a boro-phospho-silicate glass (BPSG) film may be used instead of the PSG film. The insulating film 14 contains silicon (Si), oxygen (O), phosphorus (P), and boron (B).

In this case, a B concentration in the insulating film 14 is higher than a B concentration in the insulating film 13. The insulating film 14 contains B atoms in a high concentration, and the insulating film 13 does not contain B atoms or contains the B atoms in a low concentration. A value of the B concentration in the insulating film 13 is, for example, less than 1.0 × 10¹⁸ cm⁻³. A value of the B concentration in the insulating film 14 is, for example, 1.0 × 10¹⁸ cm⁻³ to 1.0 × 10²² cm⁻³. The P concentration in the insulating films 13 and 14 when the insulating film 14 is a BPSG film may be set similarly to the P concentration in the insulating films 13 and 14 when the insulating film 14 is a PSG film.

When the insulating film 14 is a BPSG film, the region R2 contains the B atoms in a high concentration, and the region R1 does not contain B atoms or contains the B atoms in a low concentration. As described above, the B concentration in the region R1 is, for example, less than 1.0 × 10¹⁸ cm⁻³. Meanwhile, the B concentration in the region R2 is, for example, 1.0 × 10¹⁸ cm⁻³ to 1.0 × 1022 cm⁻³. The P concentration in the regions R1 and R2 when the insulating film 14 is a BPSG film may be set similarly to the P concentration in the regions R1 and R2 when the insulating film 14 is a PSG film.

As described later, the insulating film 14 is formed by, for example, forming the source electrode 3 and the gate wiring 6 on the insulating film 13 and implanting P ions and B ions into the insulating film 13 using the source electrode 3 and the gate wiring 6 as a mask. In this case, the P ions and the B ions arrive at the upper surface of the insulating film 13 exposed between the source electrode 3 and the gate wiring 6, and a part of the insulating film 13 is changed to the insulating film 14. The insulating film 14 is thus formed between the source electrode 3 and the gate wiring 6. At this time, the P atoms and the B atoms may enter the source electrode 3 or the gate wiring 6, or the P atoms and the B atoms may adhere to the surface of the source electrode 3 or the gate wiring 6. In this case, a semiconductor device product may contain the P atoms and the B atoms inside or on the surface of the source electrode 3 or the gate wiring 6.

FIG. 7 is a cross-sectional view showing a structure of a semiconductor device according to a modification of the first embodiment. FIG. 8 is a plan view showing the structure of the semiconductor device according to the modification of the first embodiment. FIG. 7 shows a cross section taken along a line D-D′ in FIG. 8. It is noted that, in order to make the drawing easy to see, the cross section shown in FIG. 7 is shown with a width of the planar portion 21 in the X direction and a width of the pad portion 23 in the X direction being shorter than widths thereof in FIG. 8.

FIG. 7 shows the regions R1 and R2 according to the present modification. In the present modification, the region R1 is present below the source electrode 3 and the gate wiring 6, and the region R2 is present between the source electrode 3 and the gate wiring 6. It is noted that the region R2 according to the present modification expands to the region below the source electrode 3 and the gate wiring 6.

FIG. 7 shows a width W1 between the source electrode 3 and the gate wiring 6 and a width W2 of the region R2. Since the region R2 according to the present modification protrudes to the region below the source electrode 3 and the gate wiring 6, the width W2 is larger than the width W1 (W2 > W1).

FIG. 7 further shows a protrusion width ΔW of the region R2. The region R2 according to the present modification protrudes by the protrusion width ΔW to the region below the source electrode 3 and the gate wiring 6. When the region R2 isotropically protrudes, the protrusion width ΔW is obtained by an equation of ΔW = (W2-W1)/2. The protrusion width ΔW is about, for example, 1 µm.

In FIG. 8, a region occupied by the source electrode 3 and the gate wiring 6 is indicated by dot hatching, and other regions are indicated by white. The region R1 in the modified first embodiment is narrower than the region indicated by dot hatching. Meanwhile, the region R2 in the modified first embodiment is wider than the region indicated by white. In FIG. 8, lines shown around the source electrode 3 and the gate wiring 6 indicate boundary lines between the region R1 and the region R2.

As described later, the insulating film 14 is formed by, for example, forming the source electrode 3 and the gate wiring 6 on the insulating film 13 and implanting P ions and B ions into the insulating film 13 using the source electrode 3 and the gate wiring 6 as a mask. At this time, the insulating film 14 shown in FIG. 5 may be formed by, for example, implanting the P ions and the B ions in parallel to the Z direction. Meanwhile, the insulating film 14 shown in FIG. 7 may be formed by, for example, obliquely implanting the P ions and the B ions with respect to the Z direction. That is, the insulating film 14 shown in FIG. 7 may be formed by oblique implantation with the P ions and the B ions.

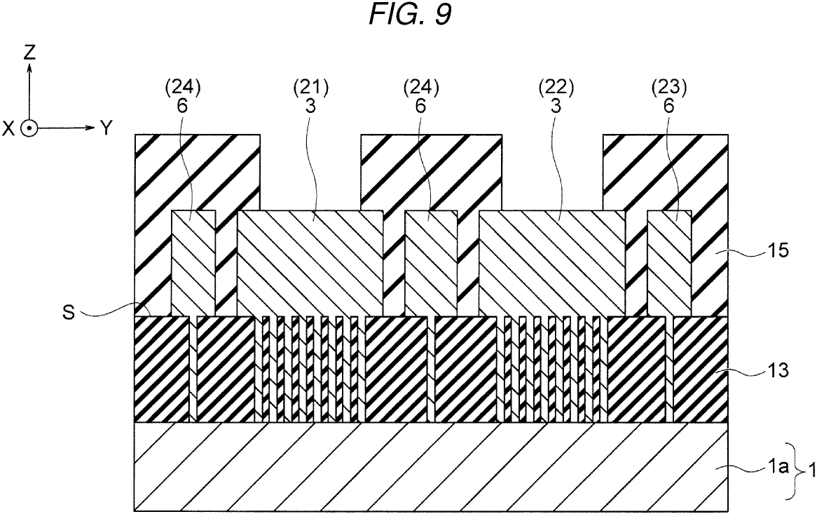

FIG. 9 is a cross-sectional view showing a structure of a semiconductor device according to a first comparative example.

As shown in FIG. 9, the semiconductor device according to the present comparative example includes the insulating film 13 alone instead of the insulating films 13 and 14. Therefore, the upper surface S according to the present comparative example is the upper surface of the insulating film 13. As described above, the insulating film 13 is, for example, an NSG film.

In the present comparative example, there is a problem that movable ions enter cells of the power MOSFET from a gap between the source electrode 3 and the gate wiring 6. As a result, threshold voltages of neighboring cells may decrease.

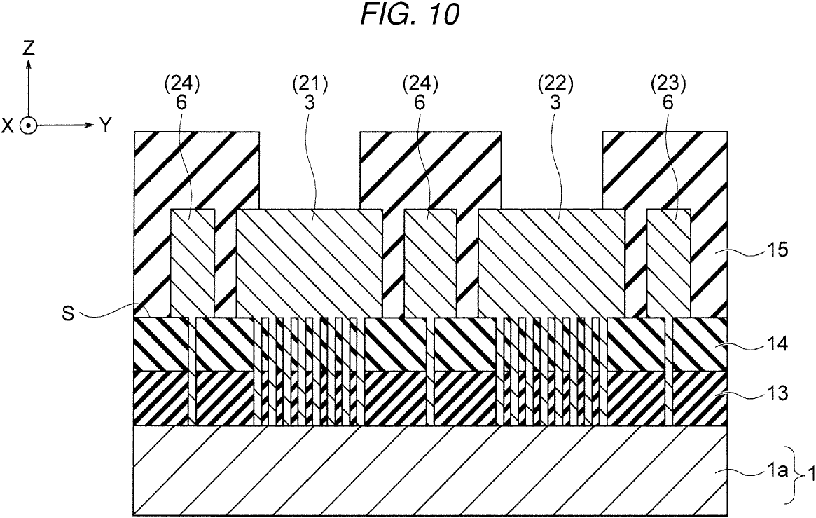

FIG. 10 is a cross-sectional view showing a structure of a semiconductor device according to a second comparative example.

As shown in FIG. 10, the semiconductor device according to the present comparative example includes the insulating films 13 and 14. It is noted that the insulating film 14 according to the present comparative example is formed on the entire upper surface of the insulating film 13. Therefore, the upper surface S according to the present comparative example is the upper surface of the insulating film 14. As described above, the insulating film 14 is, for example, a PSG film (or a BPSG film).

According to the present comparative example, by exposing the insulating film 14 in the gap between the source electrode 3 and the gate wiring 6, movable ions can be gettered by the insulating film 14. Accordingly, a decrease in threshold voltage can be prevented.

However, when a phosphorus oxide (and a boron oxide) is formed when the insulating film 14 absorbs moisture, a defect may occur in the power MOSFET. In addition, when phosphorus atoms (and boron atoms) in the insulating film 14 scatter to a side surface of the source electrode 3 or the gate wiring 6, avalanche capability and reverse recovery time (trr) capability of the power MOSFET may decrease.

Meanwhile, as shown in FIG. 5, the semiconductor device according to the present embodiment includes the insulating films 13 and 14 such that the upper surface S is the upper surfaces of the insulating films 13 and 14. Specifically, the region R1 is present below the source electrode 3 and the gate wiring 6, and the region R2 is present between the source electrode 3 and the gate wiring 6.

Therefore, according to the present embodiment, by exposing the insulating film 14 in the gap between the source electrode 3 and the gate wiring 6, the movable ions can be gettered by the insulating film 14. In addition, according to the present embodiment, a moisture absorption amount of the insulating film 14 and a scattering amount of phosphorus atoms (and the boron atoms) can be reduced by reducing a ratio of the insulating film 14 to the upper surface S. Accordingly, the disadvantage of the insulating film 14 can be reduced while benefitting from the advantage provided by the insulating film 14.

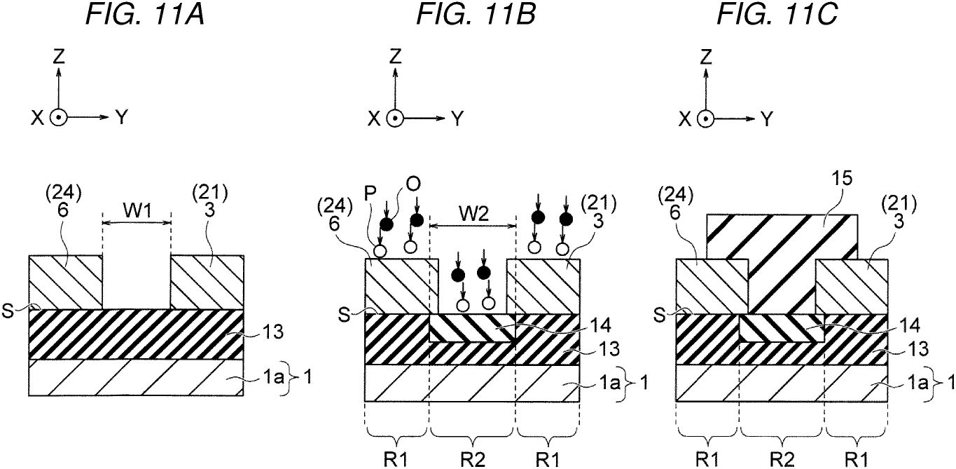

(2) Method for Manufacturing Semiconductor Device Next, three examples of a method for forming the insulating films 13 and 14 according to the present embodiment will be described with reference to FIGS. 11A to 11C to FIGS. 13A to 13C.

FIGS. 11A to 11C are cross-sectional views showing a first example of the method for manufacturing the semiconductor device according to the first embodiment.

First, the insulating film 13 is formed on the semiconductor layer 1, and the source electrode 3 and the gate wiring 6 are formed on the insulating film 13 (FIG. 11A). The source electrode 3 and the gate wiring 6 are formed by, for example, forming a material common to the source electrode 3 and the gate wiring 6 on the insulating film 13 and processing the material by lithography and reactive ion etching (RIE). FIG. 11A shows the width W1 between the source electrode 3 and the gate wiring 6.

Next, ion implantation into the insulating film 13 is performed using the source electrode 3 and the gate wiring 6 as a mask (FIG. 11B). At this time, phosphorus (P) and oxygen (O) are used for the ion implantation. As a result, the insulating film 14 is formed in the insulating film 13. The insulating film 13 is, for example, a SiO₂ film (NSG film). Therefore, the insulating film 14 is a SiO₂ film (PSG film) into which P atoms and O atoms obtained by the ion implantation are introduced.

In the ion implantation, the P ions and the O ions are selectively implanted into the insulating film 13 between the source electrode 3 and the gate wiring 6. Accordingly, the upper surface S including the regions R1 and R2 can be formed. The region R1 is formed below the source electrode 3 and the gate wiring 6, and the region R2 is formed between the source electrode 3 and the gate wiring 6. The P concentration in the region R2 is higher than the P concentration in the region R1. The P ions and the O ions may be simultaneously implanted into the insulating film 13, or may be sequentially implanted into the insulating film 13.

In the ion implantation, vertical irradiation may be performed with ions, or oblique irradiation may be performed with ions. The regions R1 and R2 with shapes shown in FIG. 5 can be formed by the vertical irradiation, and the regions R1 and R2 with shapes shown in FIG. 7 can be formed by the oblique irradiation. FIG. 11B shows a result of the oblique irradiation, that is the region R2 that protrudes into the region below the source electrode 3 and the gate wiring 6. FIG. 11B shows the width W2 of the region R2. The region R2 that protrudes into the region below the source electrode 3 and the gate wiring 6 may be formed for a reason different from the oblique irradiation, for example, may be formed by diffusion of the introduced P atoms into the insulating film 14.

The O ions are used for the ion implantation, for example, in order to form a P-O bond in the insulating film 14. A ratio of the number of the P atoms and the number of the O atoms introduced into the insulating film 14 is desirably about, for example, 2:5.

Next, the insulating film 15 is formed on the source electrode 3, the gate wiring 6, and the insulating film 14 (FIG. 11C). In this way, the semiconductor device according to the present embodiment is manufactured. The drain electrode 2, the gate electrode 4, and the field plate electrode 5 are formed, for example, before the step in FIG. 11A is performed. During that process, the drain electrode 2 is formed on one surface of the semiconductor layer 1, and the source electrode 3 and the gate wiring 6 are formed on the other surface of the semiconductor layer 1.

The ion implantation described above may be performed using P ions, O ions, and boron (B) ions. In this case, the insulating film 14 is a SiO₂ film (BPSG film) into which P atoms, O atoms, and B atoms obtained by the ion implantation are introduced. The P concentration and the B concentration in the region R2 are higher than the P concentration and the B concentration in the region R1, respectively. The P ions, the O ions, and the B ions may be simultaneously implanted into the insulating film 13, or may be sequentially implanted into the insulating film 13.

In addition, in the ion implantation described above, the P atoms and the B atoms may enter the source electrode 3 or the gate wiring 6, or the P atoms and the B atoms may adhere to the surface of the source electrode 3 or the gate wiring 6. In this case, a semiconductor device product may contain the P atoms and the B atoms inside or on the surface of the source electrode 3 or the gate wiring 6.

In addition, after the ion implantation described above is performed, annealing the insulating films 13 and 14 may or may not be performed. For example, when performance of the insulating film 14 is to be improved by the annealing, the annealing is performed. On the other hand, when the performance of the insulating film 14 is not to be improved or to be slightly improved by the annealing, the annealing is not performed.

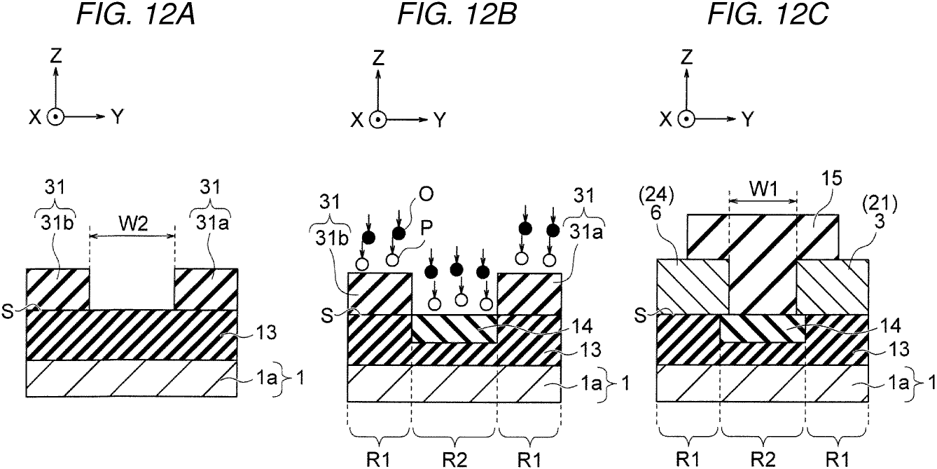

FIGS. 12A to 12C are cross-sectional views showing a second example of the method for manufacturing the semiconductor device according to the first embodiment. The descriptions of FIGS. 12A to 12C that are common to the descriptions of FIGS. 11A to 11C will be omitted as appropriate.

First, the insulating film 13 is formed on the semiconductor layer 1, a resist film 31 is formed on the insulating film 13, and the resist film 31 is patterned into resist patterns 31a and 31b (FIG. 12A). The resist patterns 31a and 31b have a shape in a plan view same as that of the region R1 to be formed later. FIG. 12A shows a width between the resist pattern 31a and the resist pattern 31b, which is the width W2 of the region R2 to be formed later. The resist film 31 is an example of a first film.

Next, ion implantation into the insulating film 13 is performed using the resist patterns 31a and 31b as a mask (FIG. 12B). As a result, the insulating film 14 is formed in the insulating film 13. When P ions and O ions are implanted, the insulating film 14 is a PSG film. When P ions, O ions, and B ions are implanted, the insulating film 14 is a BPSG film.

In the ion implantation, the P ions and the like are selectively implanted into the insulating film 13 between the resist pattern 31a and the resist pattern 31b. Accordingly, the upper surface S including the regions R1 and R2 can be formed. The region R1 is formed below the resist patterns 31a and 31b, and the region R2 is formed between the resist pattern 31a and the resist pattern 31b. FIG. 12B shows a result of vertical irradiation with ions, that is, the region R2 that does not protrude into the region below the resist patterns 31a and 31b. At this time, oblique irradiation may be performed instead of the vertical irradiation.

Next, the resist patterns 31a and 31b are removed, the source electrode 3 and the gate wiring 6 are formed on the insulating films 13 and 14, and the insulating film 15 is formed on the source electrode 3, the gate wiring 6, and the insulating film 14 (FIG. 12C). Most parts of the source electrode 3 and the gate wiring 6 are disposed above the region R1. In this way, the semiconductor device according to the present embodiment is manufactured. FIG. 12C shows the width W1 between the source electrode 3 and the gate wiring 6.

According to the second example, by performing the vertical irradiation instead of the oblique irradiation, the region R2 that protrudes into the region below the source electrode 3 and the gate wiring 6 can be formed. Meanwhile, according to the first example, the regions R1 and R2 can be formed without using the resist film 31.

The region R2 in the second example may be formed in a shape different from that of the region R2 in the first example. For example, the region R2 in the second example may be formed in only a part of the region between the source electrode 3 and the gate wiring 6. This may be achieved by, for example, setting the shape of the resist patterns 31a and 31b such that the region R2 is formed in only a part of the region between the source electrode 3 and the gate wiring 6.

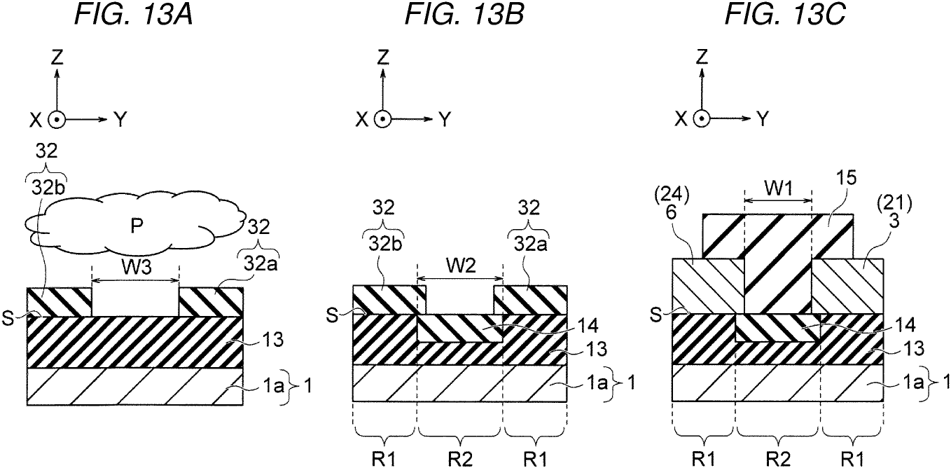

FIGS. 13A to 13C are cross-sectional views showing a third example of the method for manufacturing the semiconductor device according to the first embodiment. The descriptions of FIGS. 13A to 13C that are common to the descriptions of FIGS. 11A to 11C will be omitted as appropriate.

First, the insulating film 13 is formed on the semiconductor layer 1, a hard mask film 32 is formed on the insulating film 13, and the hard mask film 32 is processed into mask patterns 32a and 32b by lithography and RIE (FIG. 13A). The mask patterns 32a and 32b have a shape in a plan view substantially same as that of the region R1 to be formed later. FIG. 13A shows a width W3 between the mask pattern 32a and the mask pattern 32b. The hard mask film 32 is, for example, a SiN film. The hard mask film 32 is also an example of the first film.

Next, a gas containing P atoms and O atoms is supplied to the insulating film 13, and the insulating film 13 is exposed to the gas (FIG. 13A). At this time, the mask patterns 32a and 32b are used as gas supplying masks. As a result, the P atoms and the O atoms are introduced into the insulating film 13, and the insulating film 14 is formed in the insulating film 13 (FIG. 13B). The gas is, for example, POCl₂ gas. The gas may further contain B atoms. When P atoms and O atoms are introduced, the insulating film 14 is a PSG film. When P atoms, O atoms, and B atoms are introduced, the insulating film 14 is a BPSG film.

In the gas supply, the P atoms and the like are selectively introduced into the insulating film 13 between the mask pattern 32a and the mask pattern 32b. Accordingly, the upper surface S including the regions R1 and R2 can be formed. The region R1 is formed below the mask patterns 32a and 32b, and the region R2 is formed between the mask pattern 32a and the mask pattern 32b. In addition, in the gas supply, the P atoms and the like are isotropically introduced into the insulating film 13. Therefore, the region R2 shown in FIG. 13B protrudes into the region below the mask patterns 32a and 32b. FIG. 13B shows the width W2 of the region R2 wider than the width W3.

Next, the mask patterns 32a and 32b are removed, the source electrode 3 and the gate wiring 6 are formed on the insulating films 13 and 14, and the insulating film 15 is formed on the source electrode 3, the gate wiring 6, and the insulating film 14 (FIG. 13C). Most parts of the source electrode 3 and the gate wiring 6 are disposed above the region R1. In this way, the semiconductor device according to the present embodiment is manufactured. FIG. 13C shows the width W1 between the source electrode 3 and the gate wiring 6.

According to the third example, by the gas supply, the region R2 that protrudes into the region below the source electrode 3 and the gate wiring 6 can be easily formed. For example, the gas supply can be performed by batch processing of simultaneously processing a plurality of semiconductor layers 1 (for example, a plurality of semiconductor substrates). The gas supply is also referred to as phosphorus diffusion or gas phase diffusion. Meanwhile, according to the first example, the regions R1 and R2 can be formed without using the hard mask film 32.

The region R2 in the third example may be formed in a shape different from that of the region R2 in the first example. For example, the region R2 in the third example may be formed in only a part of the region between the source electrode 3 and the gate wiring 6. This may be achieved by, for example, setting the shape of the mask patterns 32a and 32b such that the region R2 is formed in only a part of the region between the source electrode 3 and the gate wiring 6.

The gas supply shown in FIG. 13A may be performed at a high temperature (for example, about 800° C.). In this case, the hard mask film 32 is desirably formed of a material that can withstand a high temperature. The hard mask film 32 may be a film other than the SiN film as long as the film can withstand a high temperature.

The insulating film 14 may be formed by a method other than those of the first to third examples. For example, an opening may be formed in the insulating film 13 by lithography and RIE, and the insulating film 14 may be embedded in the opening. In this case, the opening is formed in a region in which the region R2 is scheduled to be formed.

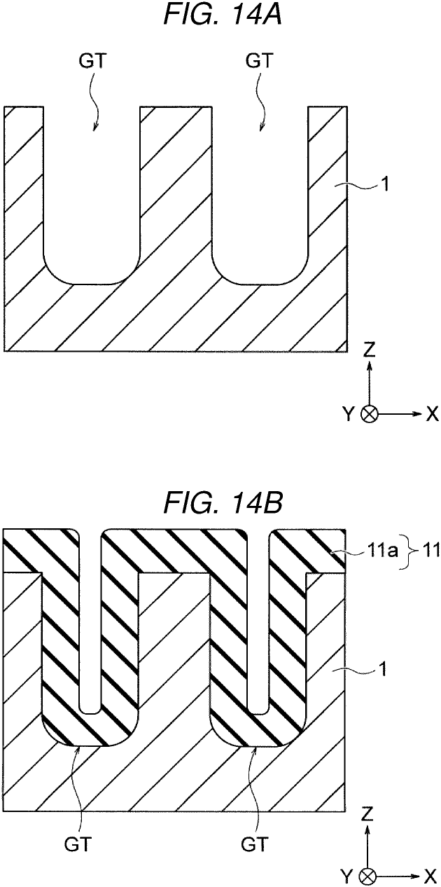

Next, the method for manufacturing the semiconductor device according to the present embodiment will be described in detail with reference to FIGS. 14A and 14B to FIGS. 22A and 22B.

FIGS. 14A and 14B to FIGS. 22A and 22B are cross-sectional views showing details of the method for manufacturing the semiconductor device according to the first embodiment.

First, the plurality of gate trenches GT are formed in the semiconductor layer 1 by lithography and RIE (FIG. 14A). These gate trenches GT are each formed to extend in the Y direction and adjacent to each other in the X direction.

Next, an insulating film 11a for the insulating film 11 is formed on the entire surface of the semiconductor layer 1 (FIG. 14B). As a result, the insulating film 11a is formed on side surfaces and a bottom surface of each gate trench GT. The insulating film 11a is, for example, a SiO₂ film.

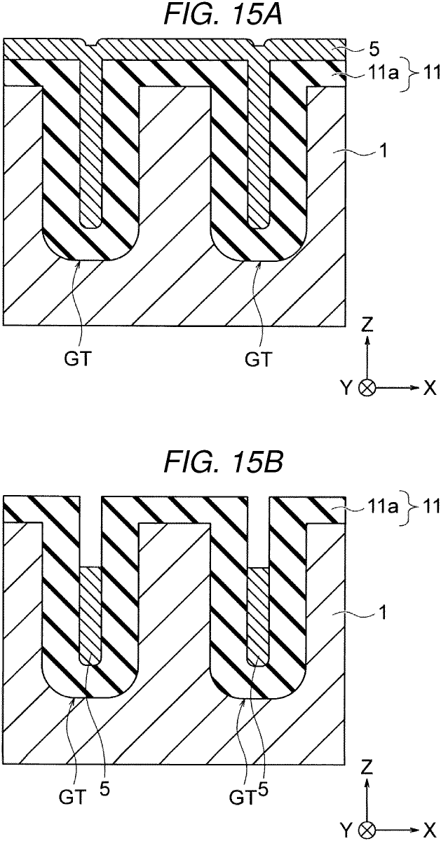

Next, a material of the field plate electrode 5 is formed on the entire surface of the semiconductor layer 1 (FIG. 15A). As a result, the material is formed in each gate trench GT via the insulating film 11a. The material is, for example, a polysilicon layer.

Next, the material of the field plate electrode 5 is processed by wet etching (FIG. 15B). As a result, a part of the material is removed outside the gate trenches GT, and the other part of the material remains in the gate trenches GT and is formed as the field plate electrode 5 in each gate trench GT.

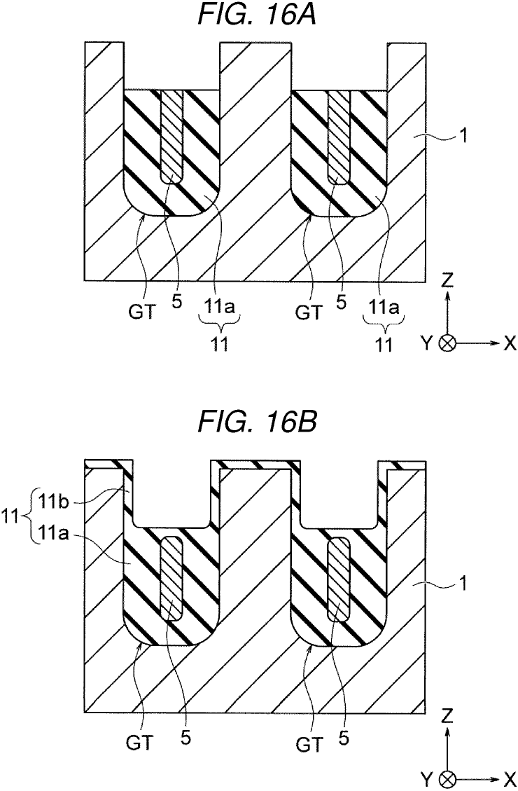

Next, the insulating film 11a is processed by the wet etching (FIG. 16A). As a result, a part of the insulating film 11a is removed outside the gate trenches GT, and the other part remains in the gate trenches GT.

Next, surfaces of the semiconductor layer 1 and the field plate electrode 5 are thermally oxidized (FIG. 16B). As a result, a thermal oxide film is formed as an insulating film 11b for the insulating film 11 on the surfaces of the semiconductor layer 1 and the field plate electrode 5. The insulating film 11b is, for example, a SiO₂ film.

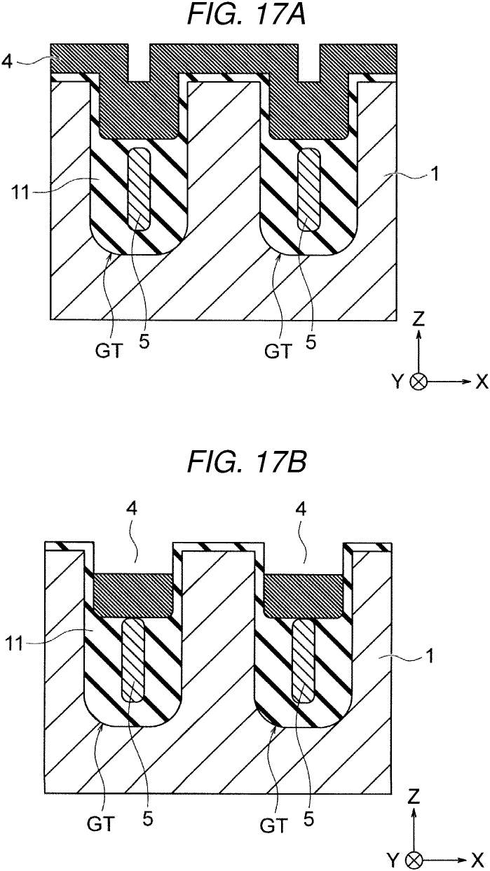

Next, a material of the gate electrode 4 is formed on the entire surface of the semiconductor layer 1 (FIG. 17A). As a result, the material is formed in each gate trench GT via the insulating film 11. The material is, for example, a polysilicon layer.

Next, the material of the gate electrode 4 is processed by wet etching (FIG. 17B). As a result, a part of the material that is outside the gate trenches GT is removed, and the other part of the material remains in the gate trenches GT and is formed as the gate electrode 4 in each gate trench GT.

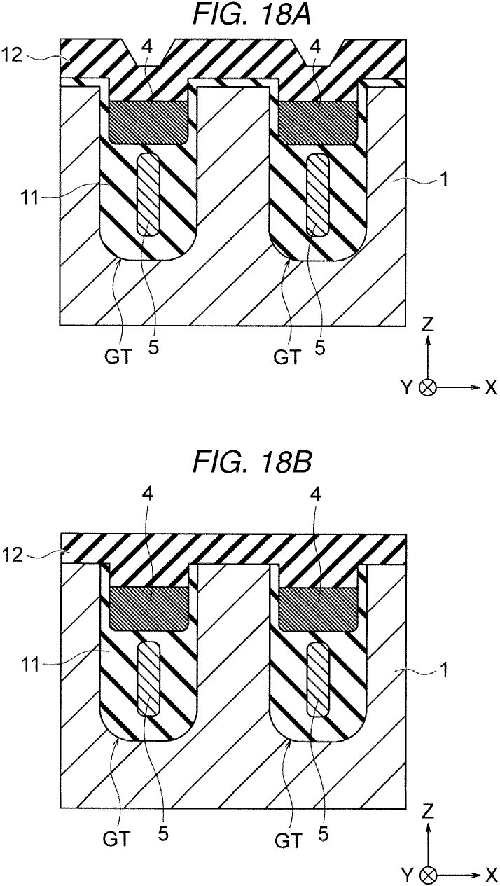

Next, the insulating film 12 is formed on the entire surface of the semiconductor layer 1 by chemical vapor deposition (CVD) (FIG. 18A). As a result, the insulating film 12 is formed in each gate trench GT via the gate electrode 4. The insulating film 12 is, for example, a SiO₂ film.

Next, a heat treatment is performed on the insulating film 12 (FIG. 18B). As a result, the insulating film 12 is softened, and then a surface of the insulating film 12 is planarized.

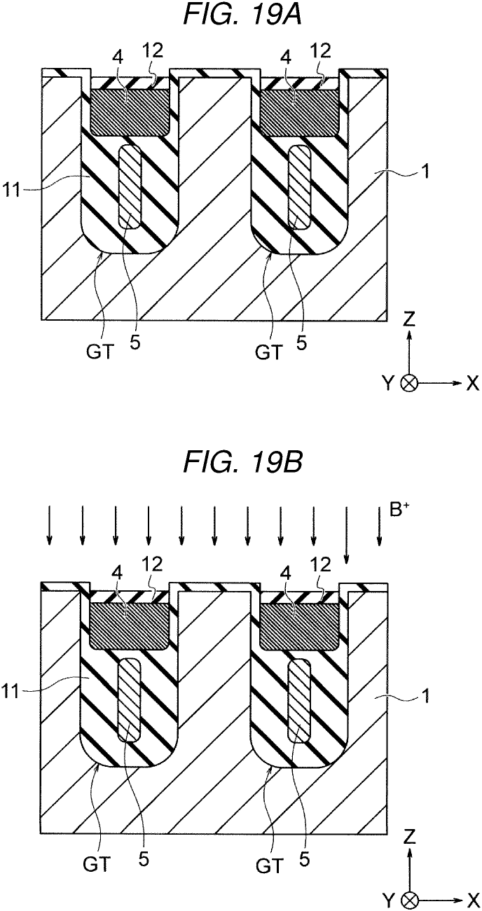

Next, the insulating film 12 is processed by dry etching (FIG. 19A). As a result, a part of the insulating film 12 outside the gate trenches GT is removed, and the other part remains in the gate trenches GT.

Next, ion implantation of p-type impurity ions from the upper surface side of the semiconductor layer 1 is performed (FIG. 19B). As a result, p-type impurity atoms are introduced into the semiconductor layer 1 and the like. A p-type impurity is, for example, boron (B).

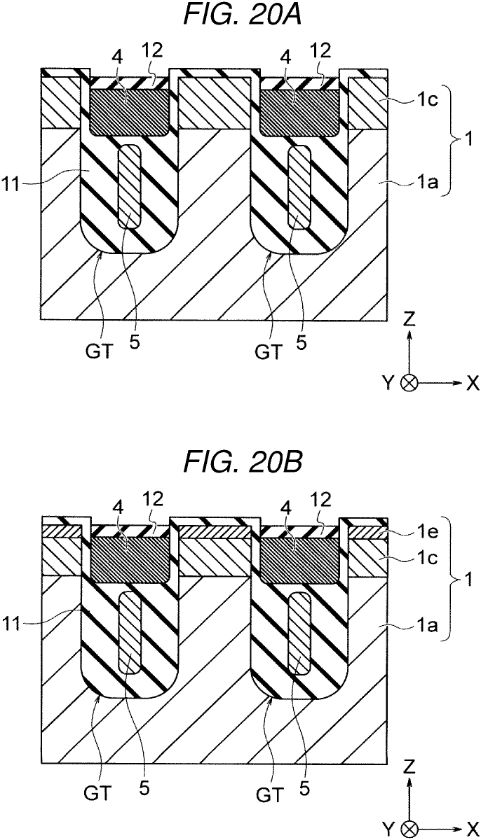

Next, a heat treatment is performed on the semiconductor layer 1 (FIG. 20A). As a result, the p-type impurity described above is activated and diffused in the semiconductor layer 1, and the base layer 1c is formed in the semiconductor layer 1. A region below the base layer 1c in the semiconductor layer 1 is the drift layer 1a.

Next, ion implantation of n-type impurity ions from the upper surface side of the semiconductor layer 1 is performed, and the heat treatment is performed on the semiconductor layer 1 (FIG. 20B). As a result, the n-type impurity atoms are introduced into the semiconductor layer 1 and the like, an n-type impurity is activated and diffused in the semiconductor layer 1, and the source layer 1e is formed on the base layer 1c in the semiconductor layer 1. The n-type impurity is, for example, phosphorus (P).

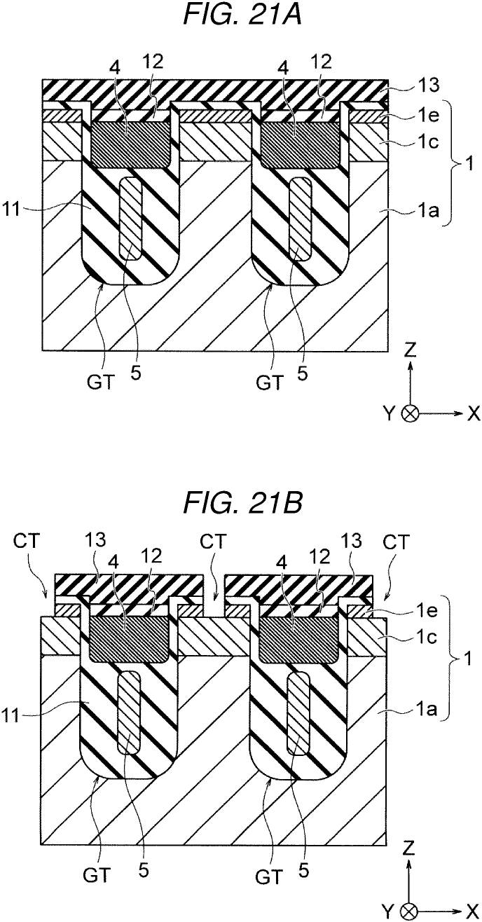

Next, the insulating film 13 is formed on the entire surface of the semiconductor layer 1 by CVD (FIG. 21A). As a result, the insulating film 13 is formed on the insulating film 12, the gate electrode 4, and the insulating film 11. The insulating film 13 is, for example, an NSG film (a SiO₂ film) .

Next, a plurality of contact trenches CT are formed in the insulating film 13, the insulating film 11, and the semiconductor layer 1 by lithography and RIE (FIG. 21B). As a result, the base layer 1c is exposed in the corresponding contact trench CT. These contact trenches CT are each formed to extend in the Y direction and adjacent to each other in the X direction.

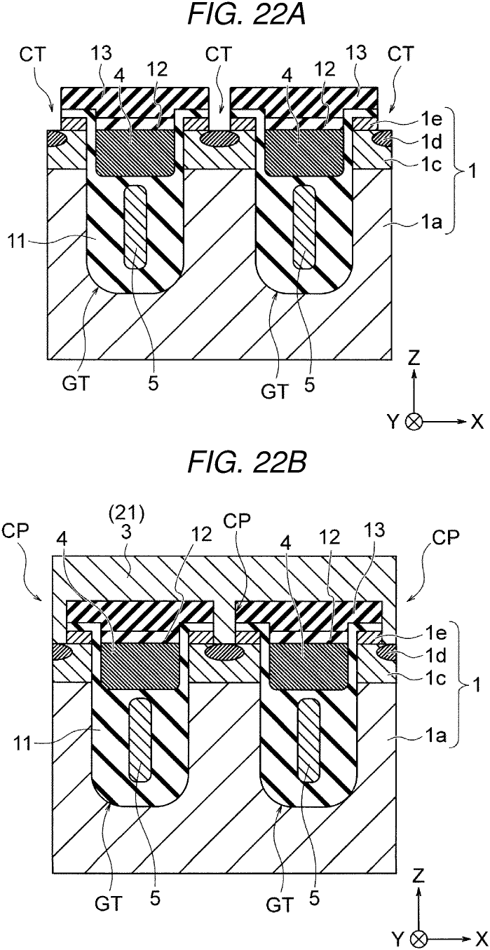

Next, ion implantation of p-type impurity ions from the contact trench CT into the semiconductor layer 1 is performed, and a heat treatment is performed on the semiconductor layer 1 (FIG. 22A). As a result, the p-type impurity atoms are introduced into the semiconductor layer 1, the p-type impurity is activated and diffused in the semiconductor layer 1, and the contact layer 1d is formed on the base layer 1c in the semiconductor layer 1. The p-type impurity is, for example, boron (B).

Next, a material of the source electrode 3 is formed on the entire surface of the semiconductor layer 1, and the material is processed by lithography and RIE (FIG. 22B). As a result, the source electrode 3 is formed on the insulating film 13. A part of the source electrode 3 enters the contact trench CT. As a result, the contact portion CP is formed in the corresponding contact trench CT, and the contact portion CP is formed on the corresponding contact layer 1d. In this way, the semiconductor device according to the present embodiment is manufactured.

The gate wiring 6 is formed of, for example, the material of the source electrode 3 at the same time as the source electrode 3. In this case, before the gate wiring 6 and the source electrode 3 are formed, openings for embedding the field plate contacts FPC and the gate contacts GC are formed in the insulating films 13 and 12 (see FIG. 4).

In addition, the drain electrode 2 and the drain layer 1b are formed, for example, before the step in FIG. 14A is performed. The drain layer 1b is formed in the semiconductor layer 1 from the surface of the semiconductor layer 1 on which the drain electrode 2 is formed.

In addition, the insulating films 14 and 15 may be formed by the methods of the first to third examples described with reference to FIGS. 11A to 11C to FIGS. 13A to 13C. In this case, the insulating film 14 is formed, for example, before or after the formation of the source electrode 3 and the gate wiring 6. In addition, the insulating film 15 is formed, for example, after the formation of the source electrode 3 and the gate wiring 6. Accordingly, the regions R1 and R2 can be formed on the upper surface S of the base insulating film including the insulating films 13 and 14.

As described above, the semiconductor device according to the present embodiment is manufactured such that the upper surface S of the base insulating film including the insulating films 13 and 14 includes the regions R1 and R2. The region R1 has a low P concentration and is provided below the source electrode 3 and the gate wiring 6. The region R2 has a high P concentration and is provided between the source electrode 3 and the gate wiring 6. Therefore, according to the present embodiment, it is possible to form the source electrode 3 and the gate wiring 6 on the base insulating film containing phosphorus (P). According to the present embodiment, the amount of deterioration of properties of the semiconductor device can be reduced by such a structure.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor layer;
a first insulating film provided on the semiconductor layer;
a gate wiring provided on the first insulating film;
a source electrode provided on the first insulating film;
a second insulating film provided on the gate wiring and the source electrode and including a portion sandwiched between the gate wiring and the source electrode; and
a drain electrode provided below the semiconductor layer, wherein
an upper surface of the first insulating film includes a first region having a first concentration of phosphorus and a second region having a second concentration of phosphorus that is higher than the first concentration,
the first region is present between the semiconductor layer and the gate wiring and between the semiconductor layer and the source electrode, and
the second region is present between the semiconductor layer and the portion of the second insulating film.

2. The semiconductor device according to claim 1, wherein
the first concentration is less than 1.0 × 10¹⁸ cm⁻³.

3. The semiconductor device according to claim 2, wherein
the second concentration is 1.0 × 10¹⁸ cm⁻³ to 1.0 × 10²² cm⁻³.

4. The semiconductor device according to claim 3, wherein
phosphorus is present inside or on a surface of at least one of the gate wiring and the source electrode.

5. The semiconductor device according to claim 1, wherein
the first region has a third concentration of boron, and
the second region has a fourth concentration of boron that is higher than the third concentration.

6. The semiconductor device according to claim 5, wherein
the third concentration is less than 1.0 × 10¹⁸ cm⁻³.

7. The semiconductor device according to claim 6, wherein
the fourth concentration is 1.0 × 10¹⁸ cm⁻³ to 1.0 × 10²² cm⁻³.

8. The semiconductor device according to claim 1, wherein the first insulating film further includes a third region that is present between the second region and the semiconductor layer.

9. The semiconductor device according to claim 8, wherein a part of the second region is also present between the source electrode and the third region and between the gate wiring and the third region.

10. The semiconductor device according to claim 1, wherein a part of the second region is also present between the source electrode and the semiconductor layer and between the gate wiring and the semiconductor layer.

11. A method for manufacturing a semiconductor device comprising:
forming a first insulating film on a first surface of a semiconductor layer;
forming a gate wiring on the first insulating film;
forming a source electrode on the first insulating film;
forming a second insulating film on the gate wiring and the source electrode, the second insulating film including a portion sandwiched between the gate wiring and the source electrode; and
forming a drain electrode on a second surface of the semiconductor layer, wherein
a first region having a first concentration of phosphorus and a second region having a second concentration of phosphorus that is higher than the first concentration are formed on an upper surface of the first insulating film,
the first region is between the semiconductor layer and the gate wiring and between the semiconductor layer and the source electrode, and
the second region is between the semiconductor layer and the portion of the second insulating film.

12. The method of claim 11, further comprising:
implanting ions onto a part of the upper surface of the first insulating film to form the second region.

13. The method of claim 12, wherein the ions are implanted after the steps of forming the gate wiring and the source electrode.

14. The method of claim 13, wherein the ions are implanted at an oblique angle.

15. The method of claim 12, wherein the ions are implanted prior to the steps of forming the gate wiring and the source electrode.

16. The method of claim 15, wherein the ions are all implanted vertically.

17. The method of claim 12, wherein the ions include phosphorous ions and oxygen ions, and a phospho-silicate glass film is formed in the second region.

18. The method of claim 12, wherein the ions include phosphorous ions, boron ions and oxygen ions, and a boro-phospho-silicate glass film is formed in the second region.

19. The method of claim 11, further comprising:
exposing a part of the upper surface of the first insulating film to a supply of gas containing P atoms and 0 atoms to form the second region.

20. The method of claim 11, wherein the
exposing a part of the upper surface of the first insulating film to a supply of gas containing phosphorus atoms, boron atoms, and oxygen atoms to form the second region.
